(19) United States
(12) Patent Application Publication
(10) Pub. No.: US 2025/0126906 A1
(43) Pub. Date: Apr. 17, 2025

(54) IMAGE SENSING DEVICE

(71) Applicant: SK hynix Inc., Icheon-si (KR)

(72) Inventor: Ji Suk PARK, Icheon-si (KR)

(21) Appl. No.: 18/633,861

(22) Filed: Apr. 12, 2024

(30) Foreign Application Priority Data
Oct. 13, 2023 (KR) 10-2023-0137059

(51) Int. Cl. H01L 27/146

(52) U.S. Cl. CPC H10F 39/80373; H10F 39/182; H10F 39/807

(57) ABSTRACT

An image sensing device includes a semiconductor substrate, a photoelectric conversion region supported by the semiconductor substrate and configured to include first-type impurities and generate photocharges, a well region supported by the semiconductor substrate and configured to include second-type impurities and disposed over the photoelectric conversion region to contact the photoelectric conversion region within the semiconductor substrate, a floating diffusion region disposed in the well region and configured to store the photocharges, a transfer gate supported by the semiconductor substrate and configured to include a recess gate buried in the semiconductor substrate and configured to transmit the photocharges generated by the photoelectric conversion region to the floating diffusion region, and a first passivation layer supported by the semiconductor substrate and configured to include the second-type impurities, and covering side surfaces and a bottom surface of the recess gate within the semiconductor substrate.

### CROSS-REFERENCE TO RELATED APPLICATION

This patent document claims the priority and benefits of Korean patent application No. 10-2023-0137059, filed on Oct. 13, 2023, which is incorporated by reference in its entirety as part of the disclosure of this patent document.

### TECHNICAL FIELD

The technology and implementations disclosed in this patent document generally relate to an image sensing device.

### BACKGROUND

An image sensor is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

### SUMMARY

Various embodiments of the disclosed technology relate to an image sensing device capable of improving operation characteristics thereof.

In accordance with an embodiment of the disclosed technology, an image sensing device may include a semiconductor substrate configured to include a first surface and a second surface facing or opposite to the first surface; a photoelectric conversion region supported by the semiconductor substrate and configured to include first-type impurities and to generate photocharges by converting light incident upon the semiconductor substrate through the first surface; a well region supported by the semiconductor substrate and configured to include second-type impurities opposite to the first-type impurities and disposed over the photoelectric conversion region to contact the photoelectric conversion region within the semiconductor substrate; a floating diffusion region disposed in the well region and configured to store the photocharges; a transfer gate supported by the semiconductor substrate and configured to include a recess gate buried in the semiconductor substrate and configured to transmit the photocharges generated by the photoelectric conversion region to the floating diffusion region; and a first passivation layer supported by the semiconductor substrate and configured to include the second-type impurities and covering side surfaces and a bottom surface of the recess gate within the semiconductor substrate.

In accordance with another embodiment of the disclosed technology, an image sensing device may include a plurality of unit pixels arranged adjacent to each other; and a floating diffusion region disposed between the plurality of unit pixels and shared by the plurality of unit pixels. Each of the plurality of unit pixels may include a semiconductor substrate; a photoelectric conversion region disposed in the semiconductor substrate, and configured to generate photocharges through photoelectric conversion of incident light; a well region disposed over the photoelectric conversion region to contact the photoelectric conversion region within the semiconductor substrate; a recess gate buried in the semiconductor substrate and configured to transmit photocharges generated by the photoelectric conversion region to the floating diffusion region; and a first passivation layer configured to cover side surfaces and a bottom surface of the recess gate within the semiconductor substrate.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a plan view illustrating an example of a planar structure of one pixel block of a pixel array shown in FIG. 1 based on some implementations of the disclosed technology.

FIG. 3 is a cross-sectional view illustrating an example of a pixel block taken along the line A-A′ shown in FIG. 2 based on some implementations of the disclosed technology.

FIG. 4 is a cross-sectional view illustrating an example of a pixel block taken along the line B-B′ shown in FIG. 2 based on some implementations of the disclosed technology.

FIGS. 5A, 6A, 7A, and 8A are cross-sectional views illustrating examples of a method for forming the structure of FIG. 3 based on some implementations of the disclosed technology.

FIGS. 5B, 6B, 7B, and 8B are cross-sectional views illustrating examples of a method for forming the structure of FIG. 4 based on some implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device capable of improving operation characteristics thereof. The disclosed technology provides various implementations of the image sensing device that can improve operation characteristics thereof, can improve transfer efficiency of a transfer transistor, and can reduce the influence of dark sources.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

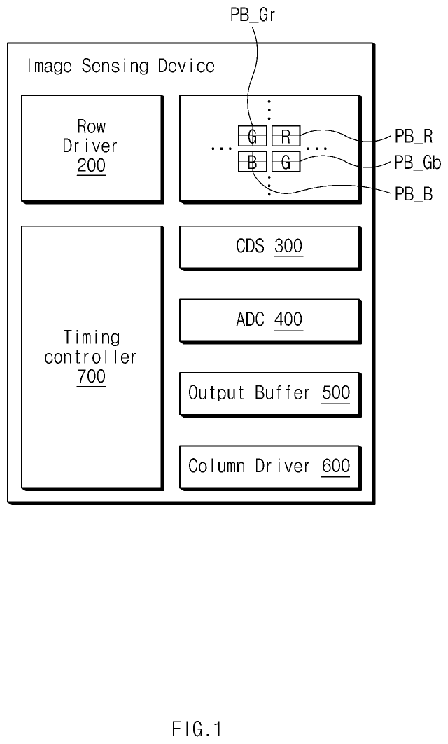

FIG. 1 is a block diagram illustrating an example of an image sensing device based on some implementations of the disclosed technology.

Referring to FIG. 1, the image sensing device may include a pixel array 100, a row driver 200, a correlated double sampler (CDS) 300, an analog-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel array 100 may include a plurality of pixel blocks (PB_R, PB_Gr, PB_Gb, PB_B) consecutively arranged in rows and columns. The pixel blocks (PB_R, PB_Gr, PB_Gb, PB_B) may be arranged adjacent to each other in a (2×2) matrix structure in a Bayer pattern. Each of the pixel blocks (PB_R, PB_Gr, PB_Gb, PB_B) may include a structure in which a plurality of unit pixels shares one floating diffusion region. Each unit pixel may include a photoelectric conversion region (e.g., a photodiode PD) for photoelectrically converting incident light to generate photocharges, and a transfer gate for transmitting photocharges generated by the photoelectric conversion region to a floating diffusion region. The transfer gate may include a recess gate buried in a semiconductor substrate. Adjacent unit pixels may be separated from each other by a trench-type pixel isolation structure.

The pixel array 100 may receive driving signals (for example, a row selection signal, a reset signal, a transmission (or transfer) signal, etc.) from the row driver 200. Upon receiving the driving signals, the unit pixels may be activated to perform the operations corresponding to the row selection signal, the reset signal, and the transfer signal.

The row driver 200 may activate the pixel array 100 to perform certain operations on the unit pixels in the corresponding row based on control signals provided by controller circuitry such as the timing controller 700. In some implementations, the row driver 200 may select one or more pixel groups arranged in one or more rows of the pixel array 100. The row driver 200 may generate a row selection signal to select one or more rows from among the plurality of rows. The row driver 200 may sequentially enable the reset signal and the transfer signal for the unit pixels arranged in the selected row. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 300 may obtain a pixel signal generated only by the incident light without causing noise. In some implementations, upon receiving a clock signal from the timing controller 700, the CDS 300 may sequentially sample and hold voltage levels of the reference signal and the pixel signal, which are provided to each of a plurality of column lines from the pixel array 100. That is, the CDS 300 may sample and hold the voltage levels of the reference signal and the pixel signal which correspond to each of the columns of the pixel array 100. In some implementations, the CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals. In some implementations, the ADC 400 may be implemented as a ramp-compare type ADC. The analog-to-digital converter (ADC) 400 may compare a ramp signal received from the timing controller 700 with the CDS signal received from the CDS 300, and may thus output a comparison signal indicating the result of comparison between the ramp signal and the CDS signal. The analog-to-digital converter (ADC) 400 may count a level transition time of the comparison signal in response to the ramp signal received from the timing controller 700, and may output a count value indicating the counted level transition time to the output buffer 500.

The output buffer 500 may temporarily store column-based image data provided from the ADC 400 based on control signals of the timing controller 700. The image data received from the ADC 400 may be temporarily stored in the output buffer 500 based on control signals of the timing controller 700. The output buffer 500 may provide an interface to compensate for data rate differences or transmission rate differences between the image sensing device and other devices.

The column driver 600 may select a column of the output buffer 500 upon receiving a control signal from the timing controller 700, and sequentially output the image data, which are temporarily stored in the selected column of the output buffer 500. In some implementations, upon receiving an address signal from the timing controller 700, the column driver 600 may generate a column selection signal based on the address signal, may select a column of the output buffer 500 using the column selection signal, and may control the image data received from the selected column of the output buffer 500 to be output as an output signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column. In some implementations, the timing controller 700 may include a logic control circuit, a phase lock loop (PLL) circuit, a timing control circuit, a communication interface circuit and others.

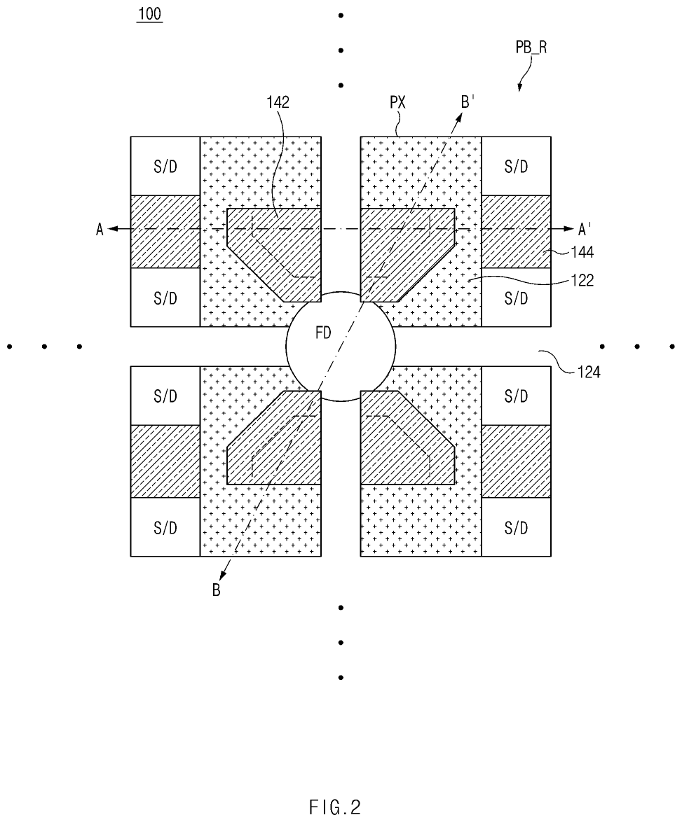

FIG. 2 is a plan view illustrating an example of a planar structure of one pixel block of the pixel array shown in FIG. 1 based on some implementations of the disclosed technology.

Since a plurality of pixel blocks has the same structure except for a difference in color between color filters, only a pixel block (PB_R) will hereinafter be described as a representative pixel block for convenience of description and better understanding of the disclosed technology.

Referring to FIG. 2, the pixel block (PB_R) may include four unit pixels (PXs) arranged adjacent to each other in a (2×2) matrix including two columns and two rows. In the example, the four unit pixels (PXs) may share one floating diffusion region (FD). For example, only one floating diffusion region (FD) configured to store photocharges generated by the unit pixels (PXs) may be formed in a central portion of the pixel block (PB_R) so that the one floating diffusion region (FD) may be shared by the unit pixels (PXs) of the pixel block (PB_R).

Each unit pixel (PX) may include two pixel transistors. For example, each unit pixel (PX) may include a transfer transistor and a drive transistor.

The transfer transistor may transmit photocharges generated by a photoelectric conversion region of the corresponding unit pixel (PX) to the floating diffusion region (FD) based on the transfer signal. The transfer transistor may be a transistor in which a photoelectric conversion region and a floating diffusion region (FD) are used as source/drain regions. A gate (i.e., transfer gate) 142 of the transfer transistor may include a recess gate, at least a portion of which is buried in a substrate to form a channel in a vertical direction.

The drive transistor may be isolated from the transfer gate 142 by a device isolation structure 122, and may include a drive gate 144 and source/drain regions (S/D) located at both sides of the drive gate 144. The drive transistor may be any one of a reset transistor configured to initialize the floating diffusion region (FD) in response to a reset signal, a source follower transistor configured to generate a pixel signal corresponding to the magnitude of photocharges stored in the floating diffusion region (FD), a selection transistor configured to output the pixel signal output from the source follower transistor to a column line in response to a row selection signal, and a conversion gain transistor configured to adjust capacitance of the floating diffusion node (FD). For example, four drive transistors of each pixel block (PB_R) may be connected to each other through a conductive line to be shared by the four unit pixels (PXs), or may be connected to the floating diffusion region (FD) to operate as any one of a reset transistor, a source follower transistor, a selection transistor, and a conversion gain transistor.

Adjacent unit pixels (PXs) may be isolated from each other by a pixel isolation structure 124, and the transfer gate 142 and the drive transistor for each unit pixel (PX) may be isolated from each other by a device isolation structure 122. Each of the device isolation structure 122 and the pixel isolation structure 124 may include a trench-type isolation structure in which an insulation material is buried in an etched region obtained by etching the substrate. For example, the device isolation structure 122 may include a shallow trench isolation (STI) structure, and the pixel isolation structure 124 may include a deep trench isolation (DTI) structure.

The transfer gate 142 and the drive transistor may be arranged symmetrical to each other between adjacent unit pixels (PXs) within the pixel block (PB_R).

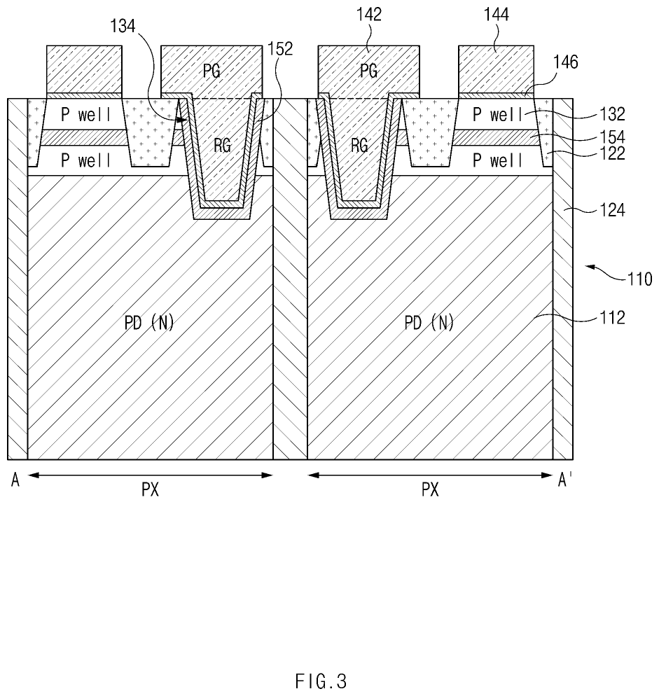

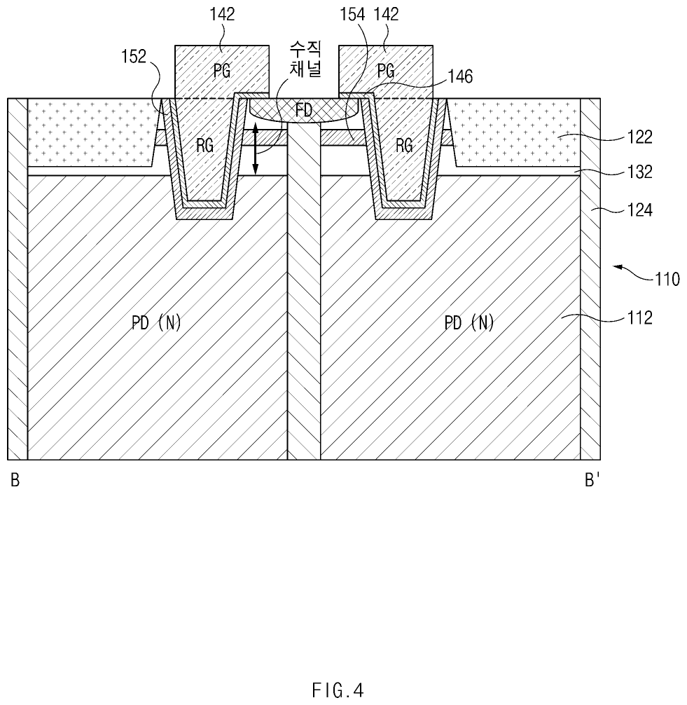

FIG. 3 is a cross-sectional view illustrating an example of the pixel block taken along the line A-A′ shown in FIG. 2 based on some implementations of the disclosed technology. FIG. 4 is a cross-sectional view illustrating an example of the pixel block taken along the line B-B′ shown in FIG. 2 based on some implementations of the disclosed technology.

Referring to FIGS. 3 and 4, a semiconductor substrate 110 may include a first surface and a second surface facing or opposite to the first surface, and may be isolated for each unit pixel (PX) by a pixel isolation structure 124. In the example, the first surface may be a surface upon which light is incident, and the second surface may be a surface in which transistors are formed. The pixel isolation structure 124 may include a DTI structure, and may be formed to penetrate the semiconductor substrate 110.

The photoelectric conversion region 112 may include N-type impurities, and may generate photocharges through photoelectric conversion of incident light. One photoelectric conversion region 112 may be formed for each unit pixel (PX), and adjacent photoelectric conversion regions 112 may be isolated from each other by the pixel isolation structure 124.

The bottom surface of the photoelectric conversion region 112 may extend to contact the second surface of the semiconductor substrate 110, and the top surface of the photoelectric conversion region 112 may extend to a position higher than a bottom surface of the transfer gate 142. For example, the photoelectric conversion region 112 may be formed to surround a lower portion of a recess gate (RG) buried in the semiconductor substrate 110 from among the transfer gates 142. In this way, the top surface of the photoelectric conversion region 112 can be formed to be higher than the bottom surface of the recess gate (RG), thereby increasing the volume of the photoelectric conversion region 112. In addition, a distance between the photoelectric conversion region 112 and the floating diffusion region (FD) is reduced, thereby improving the transfer efficiency of photocharges.

A well region 132 that forms a PN junction with the photoelectric conversion region 112 and forms a channel between transistors may be formed over the photoelectric conversion region 112 within the semiconductor substrate 110. The well region 132 may include P-type impurities. A floating diffusion region (FD) may be formed in the well region 132.

In each unit pixel (PX), the active region in which the drive transistor is formed and the recess gate (RG) may be isolated from each other by a device isolation structure 122. The device isolation structure 122 may include a trench-type STI structure. In a boundary region between unit pixels (PX), the device isolation structure 122 may be penetrated by the pixel isolation structure 124.

The transfer gate 142 may form a vertical channel between the photoelectric conversion region 112 and the floating diffusion region (FD) in response to a transfer signal, and may thus transmit photocharges generated by the photoelectric conversion region 112 to the floating diffusion region (FD). The transfer gate 142 may include a recess gate (RG), a portion of which is buried in the semiconductor substrate 110. In addition, the transfer gate 142 may include a planar gate (PG) disposed over the substrate and connected to the recess gate (RG). The planar gate (PG) may have a portion overlapping the recess gate (RG). The planar gate (PG) may have another portion overlapping a portion of the floating diffusion region (FD) in the vertical direction.

A gate insulation layer 146 may be formed under the transfer gate 142 and the drive gate 144. For example, a gate insulation layer 146 may be formed between the transfer gate 142 and the semiconductor substrate 110 and between the drive gate 144 and the semiconductor substrate 110. The gate insulation layer 146 may include an oxide layer.

A passivation layer 152 may be formed in the semiconductor substrate 110 to entirely cover the side and bottom surfaces of a trench 134 in which the recess gate RG is formed. In addition, a passivation layer 154 extending in the horizontal direction may be formed in the well region 132. The passivation layer 154 may extend to locate below the floating diffusion region (FD) and the drive transistor. For example, the passivation layer 154 may be formed to completely cross the well region 132 in the horizontal direction at a height located below the floating diffusion region (FD) within the well region 132. As a result, the well region 132 may be divided into an upper well region and a lower well region by the passivation layer 154. The upper well region corresponds to the well region disposed over the passivation layer 154 and the lower well region corresponds to the well region disposed below the passivation layer 154.

When the recess gate (RG) is formed in a trench 134 obtained by etching the semiconductor substrate 110 to a deep depth within each unit pixel (PX), a dangling bond may occur at an interface (e.g., the side and bottom surface) of the trench 134, such that excess charges (electrons) may occur as dark sources. Such excess charges may cause dark current and hot pixels, resulting in deterioration in operation characteristics of the image sensing device.

To avoid or reduce such excess charges to occur, in some implementations, a P-type passivation layer 152 with a higher concentration than the well region 132 may be formed at the interface of the trench 134 where the recess gate (RG) is formed. With the P-type passivation layer 152 having the higher concentration than the well region 132, it is possible to avoid or reduce the amount of excess charges to be generated at the interface of the trench 134.

In addition, the passivation layer 154 is formed not only below the floating diffusion region (FD) but also below the drive transistor in the well region 132, such that excess charges can be prevented from flowing into the floating diffusion region (FD) or from affecting the operation of the drive transistor. The passivation layer 154 may also reduce the influence of excess charges generated at the interface of the trench where the device isolation structure 122 is formed.

The passivation layer 154 may also contain P-type impurities having a higher concentration than the well region 132. The impurity concentrations of the passivation layers (152, 154) may be the same as or different from each other. The passivation layers (152, 154) may be connected to each other, and may be formed to have different thicknesses.

The floating diffusion region (FD) may be disposed in the well region 132 to contact the second surface of the semiconductor substrate 110. The floating diffusion region FD may contain N-type impurities.

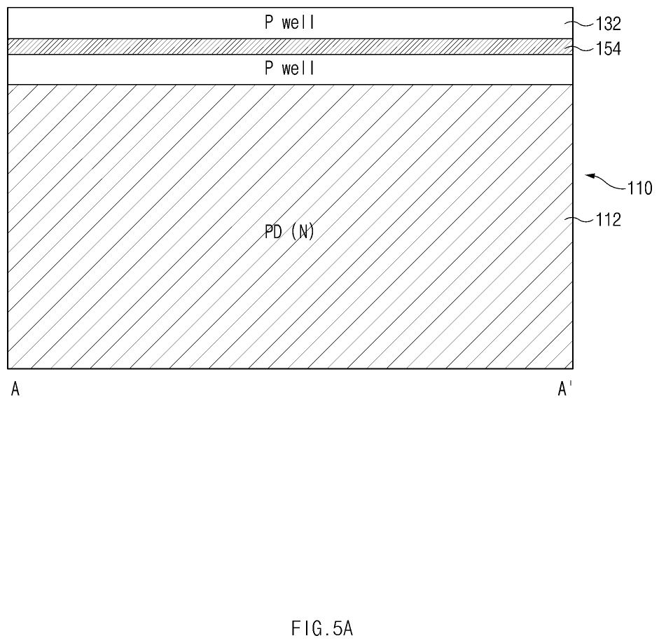

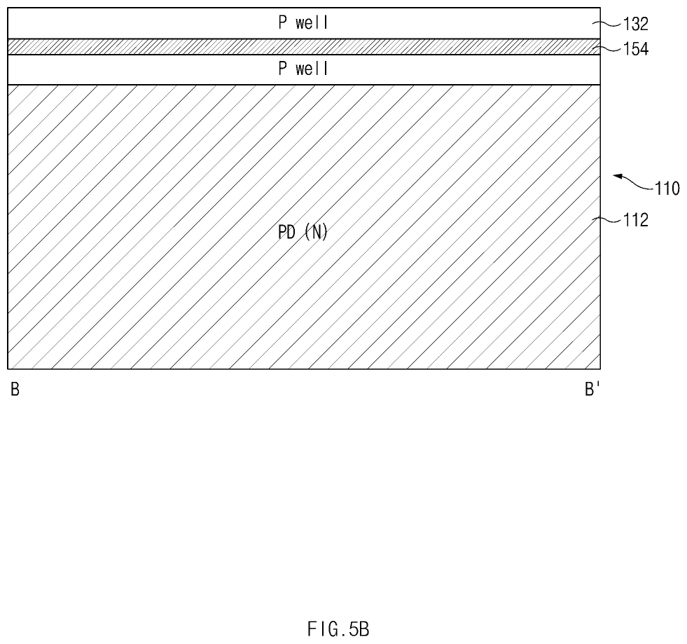

FIGS. 5A, 6A, 7A, and 8A are cross-sectional views illustrating examples of a method for forming the structure of FIG. 3 based on some implementations of the disclosed technology. FIGS. 5B, 6B, 7B, and 8B are cross-sectional views illustrating examples of a method for forming the structure of FIG. 4 based on some implementations of the disclosed technology.

Referring to FIGS. 5A and 5B, the photoelectric conversion region 112 may be formed by implanting N-type impurities into the semiconductor substrate 110 containing P-type impurities. In the semiconductor substrate 110, a region where P-type impurities remain on the photoelectric conversion region 112 may be used as the well region 132. Thus, the semiconductor substrate 110 includes the well region 132 including the P-type impurities and disposed on the photoelectric conversion region 112.

Subsequently, the passivation layer 154 may be formed by implanting P-type impurities at a certain depth within the well region 132. The passivation layer 154 may be or include a region doped with P-type impurities at a higher concentration than the well region 132. The passivation layer 154 may be formed in a horizontal direction in the entire well region 132. For example, the well region 132 may be divided into an upper region and a lower region by the passivation layer 154.

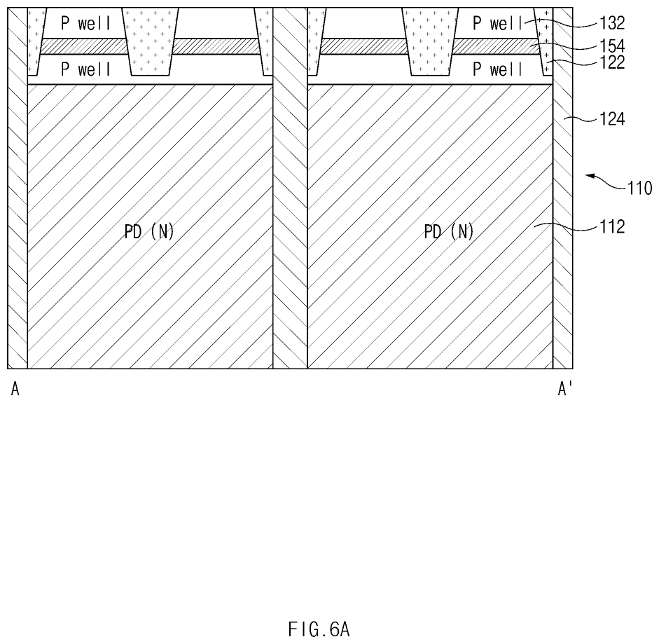

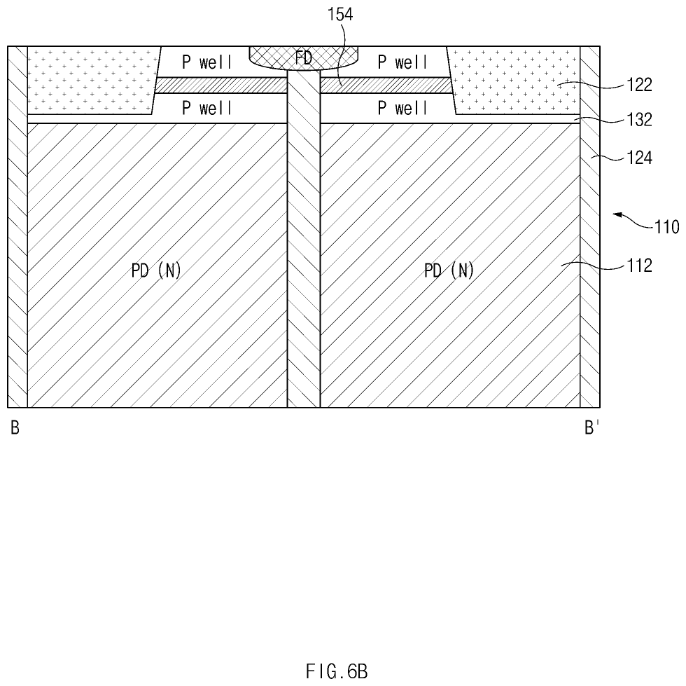

Referring to FIGS. 6A and 6B, the device isolation structure 122 may be formed in the well region 132 including the passivation layer 154, and a pixel isolation structure 124 may be formed to penetrate the device isolation structure 122 and the semiconductor substrate 110 in a boundary region between the unit pixels (PXs).

The device isolation structure 122 may define an active region in which transistors are formed within each unit pixel (PX). The device isolation structure 122 may include an STI structure, and may be formed to penetrate the passivation layer 154 within the well region 132.

The pixel isolation structure 124 may isolate the photoelectric conversion regions 112 of adjacent unit pixels (PX) from each other. The pixel isolation structure 124 may include a DTI structure.

Subsequently, the floating diffusion region (FD) may be formed in the center of each of the four adjacent unit pixels. Thus, the floating diffusion region (FD) may be formed in each pixel block. For example, a silicon layer including N-type impurities may be formed in a region from which the pixel isolation structure 124 disposed at the center of the pixel block and the upper portion of the substrate have been removed, resulting in formation of a floating diffusion region (FD).

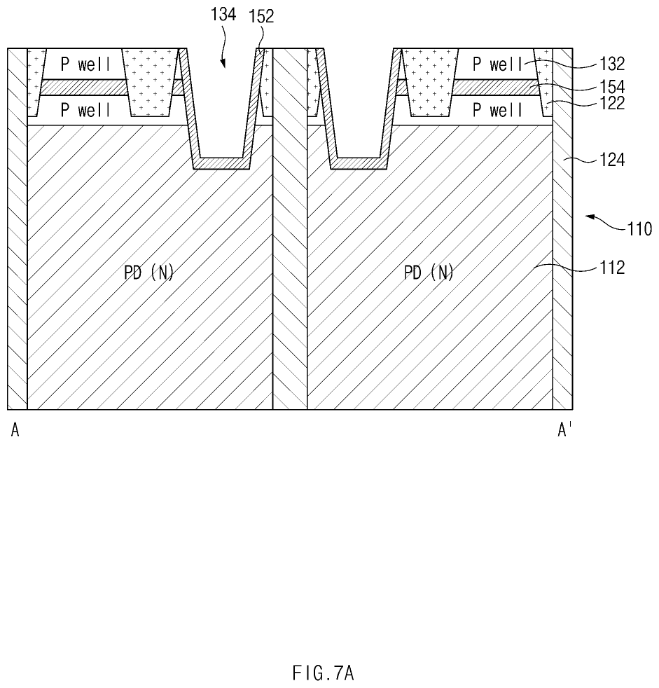

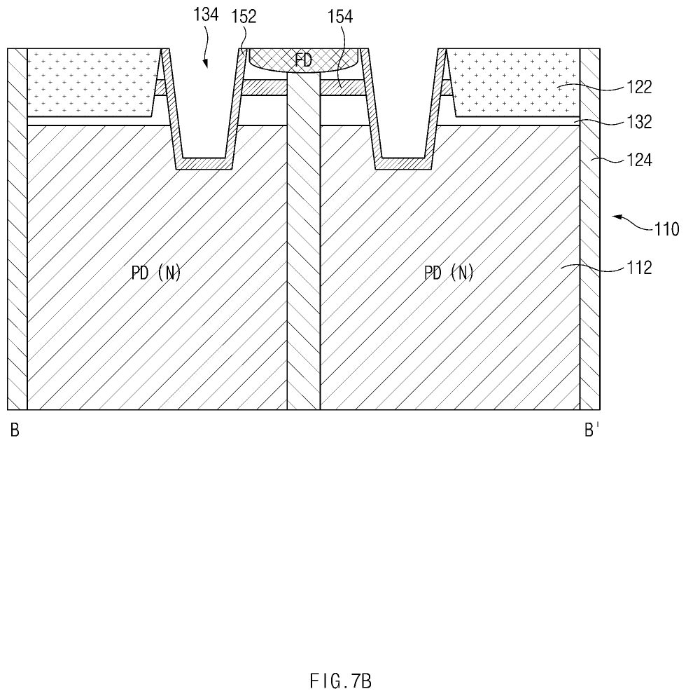

Referring to FIGS. 7A and 7B, a region to be used as a region of the recess gate (RG) within the semiconductor substrate 110 may be etched to a predetermined depth to form a trench 134. For example, the well region 132, the device isolation structure 122, and the photoelectric conversion region 112 in the region where the recess gate (RG) is to be formed may be etched to form the trench 134. The trench 134 may be formed to extend vertically to the inside of the photoelectric conversion region 112 such that a lower portion of the trench 134 is buried in the photoelectric conversion region 112. Thus, the bottom surface of the trench 134 is located below the upper surface of the photoelectric conversion region 112.

Thereafter, a mask pattern (not shown) that opens the trench 134 may be formed over the semiconductor substrate 110. Subsequently, P-type impurities may be implanted into the trench 134 such that a passivation layer 152 may be formed in the semiconductor substrate 110 to contact the sidewalls and bottom surface of the trench 134. For example, the passivation layer 152 may be formed by implanting impurities into the trench 134 through a plasma doping (PLAD) process.

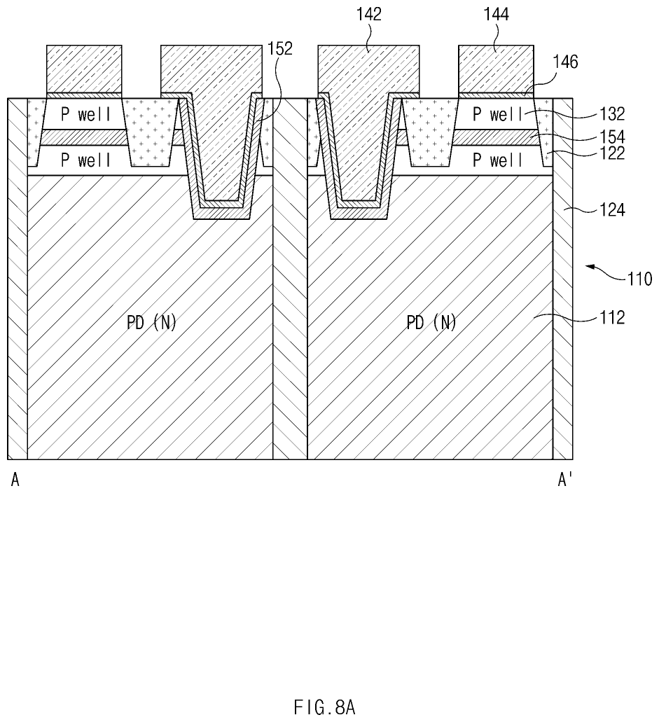

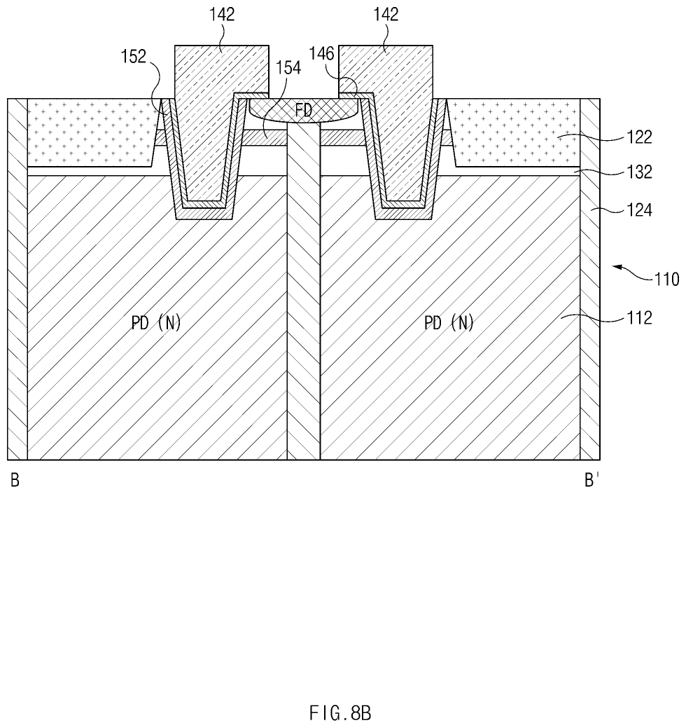

Referring to FIGS. 8A and 8B, the transfer gate 142 and the drive gate 144 may be formed not only in the trench 134 but also on the second surface of the semiconductor substrate 110.

For example, an insulation layer (not shown) may be formed not only over the side and bottom surfaces of the trench 134 but also over the second surface of the semiconductor substrate 110, and a conductive layer may be formed over the insulation layer to fill the trench 134. The insulation layer may include an oxide layer and the conductive layer may include polysilicon.

Subsequently, the transfer gate 142 and the drive gate 144 may be formed by patterning the conductive layer and the insulation layer. At this time, in the example, the patterned insulation layer may be used as the gate insulation layer 146.

The transfer gate 142 may include a recess gate (RG) buried in the semiconductor substrate 110 and a planar gate (PG) that is formed on the second surface of the semiconductor substrate 110 while contacting the recess gate (RG). The planar gate (PG) may be formed to overlap a portion of the floating diffusion region (FD).

As is apparent from the above description, the image sensing device based on some implementations of the disclosed technology can improve operation characteristics thereof.

In particular, the image sensing device based on some implementations of the disclosed technology can improve transfer efficiency of a transfer transistor.

In addition, the image sensing device based on some implementations of the disclosed technology can reduce the influence of dark sources.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device, comprising:
a semiconductor substrate configured to include a first surface and a second surface facing or opposite to the first surface;
a photoelectric conversion region supported by the semiconductor substrate and configured to include first-type impurities, and to generate photocharges by converting light incident upon the semiconductor substrate through the first surface;
a well region supported by the semiconductor substrate and configured to include second-type impurities opposite to the first-type impurities, and disposed over the photoelectric conversion region to contact the photoelectric conversion region within the semiconductor substrate;
a floating diffusion region disposed in the well region and configured to store the photocharges;
a transfer gate supported by the semiconductor substrate and configured to include a recess gate buried in the semiconductor substrate, and configured to transmit the photocharges generated by the photoelectric conversion region to the floating diffusion region; and
a first passivation layer supported by the semiconductor substrate and configured to include the second-type impurities, and covering side surfaces and a bottom surface of the recess gate within the semiconductor substrate.

2. The image sensing device according to claim 1, wherein:
the recess gate is configured to extend from the second surface toward the first surface and the recess gate penetrates the well region and is partially buried in the photoelectric conversion region.

3. The image sensing device according to claim 2, wherein the first passivation layer includes:
a first region disposed between the well region and the recess gate; and
a second region disposed between the photoelectric conversion region and the recess gate.

4. The image sensing device according to claim 1, further comprising:
a second passivation layer configured to include the second-type impurities and disposed in the well region and below the floating diffusion region.

5. The image sensing device according to claim 4, wherein:
the second passivation layer is connected to the first passivation layer.

6. The image sensing device according to claim 4, wherein:
the second passivation layer is disposed to traverse an entirety of the well region in a horizontal direction.

7. The image sensing device according to claim 4, wherein:
the first passivation layer and the second passivation layer have a same impurity concentration.

8. The image sensing device according to claim 4, wherein:
the first passivation layer and the second passivation layer have a higher concentration of impurities than the well region.

9. The image sensing device according to claim 1, wherein the transfer gate further includes:
a planar gate configured to partially overlap the floating diffusion region and contacting the recess gate.

10. An image sensing device, comprising:
a plurality of unit pixels arranged adjacent to each other; and
a floating diffusion region disposed between the plurality of unit pixels and shared by the plurality of unit pixels,
wherein each of the plurality of unit pixels includes:
a semiconductor substrate;
a photoelectric conversion region disposed in the semiconductor substrate, and configured to generate photocharges through photoelectric conversion of incident light;
a well region disposed over the photoelectric conversion region to contact the photoelectric conversion region within the semiconductor substrate;
a recess gate buried in the semiconductor substrate and configured to transmit photocharges generated by the photoelectric conversion region to the floating diffusion region; and
a first passivation layer configured to cover side surfaces and a bottom surface of the recess gate within the semiconductor substrate.

11. The image sensing device according to claim 10, wherein:
the recess gate is configured to extend in a vertical direction such that a lower region of the recess gate is buried in the photoelectric conversion region.

12. The image sensing device according to claim 11, wherein:
the first passivation layer is disposed to contact the well region and the photoelectric conversion region.

13. The image sensing device according to claim 10, wherein each of the plurality of unit pixels includes:
a second passivation layer disposed below the floating diffusion region in the well region.

14. The image sensing device according to claim 13, wherein:
the second passivation layer is connected to the first passivation layer.

15. The image sensing device according to claim 13, wherein:
the second passivation layer is disposed to traverse an entirety of the well region in a horizontal direction.

16. The image sensing device according to claim 13, wherein:
the first passivation layer and the second passivation layer include impurities having a type same as impurities of the well region, the impurities of the first passivation layer and the second passivation layer having a higher concentration than the impurities of the well region.

17. The image sensing device according to claim 10, further including:
a planar gate configured to partially overlap the floating diffusion region and contacting the recess gate.

18. The image sensing device according to claim 17, wherein the recess gate and the planar gate operate together as a transfer gate and configured to form a vertical channel between the photoelectric conversion region and the floating diffusion region.

19. The image sensing device of claim 1, further comprising:
a device isolation structure disposed in the well region and configured to define active regions in which transistors are formed.

20. The image sensing device of claim 10, further comprising:
a pixel isolation structure disposed in a boundary region between adjacent unit pixels and configured to isolate photoelectric conversion regions of adjacent unit pixels from each other.
